(19) United States
(12) Patent Application Publication
(10) Pub. No.: US 2009/0050899 A1
(43) Pub. Date: Feb. 26, 2009

(54) High-output diamond semiconductor element

(75) Inventors: Kazuhiro Ikeda, Ibaraki (JP); Hitoshi Umezawa, Ibaraki (JP); Shinichi Shikata, Ibaraki (JP); Ramanujam Kumaresan, Ibaraki (JP); Natsuo Tatsumi, Hyogo (JP)

Correspondence Address: MORGAN LEWIS & BOCKIUS LLP, 1111 PENNSYLVANIA AVENUE NW, WASHINGTON, DC, 20004, US

(73) Assignee: National Institute of Advanced Industrial Scinece and Technology

(21) Appl. No.: 12/153,752

(22) Filed: May 23, 2008

(30) Foreign Application Priority Data
Aug. 23, 2007 (JP) P. 2007-217412
Sep. 27, 2007 (JP) P. 2007-251370

(51) Int. Cl. H01L 29/15

(52) U.S. Cl. 257/77; 257/E29.072

(57) ABSTRACT

The present invention relates to a high-output diamond semiconductor element, including a Schottky electrode as a cathode, a diamond P⁻ drift layer, a diamond p⁺ ohmic layer, an ohmic electrode as an anode, and an insulating film layer disposed to surround a circumference of the Schottky electrode. It also relates to a high-output diamond semiconductor element, including a Schottky electrode as a cathode, a diamond P⁻ drift layer, a diamond p⁺ ohmic layer, an ohmic electrode as an anode, a dielectric layer disposed on a part of a junction surface of the Schottky electrode and the diamond p⁻ drift layer, and a field plate containing a conductor, the field plate being disposed on an external surface of the dielectric layer to surround a circumference of the Schottky electrode.

### FIELD OF THE INVENTION

The invention relates to a high-output diamond semiconductor element, in particular, typically to a diamond Schottky barrier diode, a diamond pn diode, a diamond thyristor, a diamond transistor and a diamond field effect transistor.

### BACKGROUND OF THE INVENTION

In conventional technologies, diamond is large in a band gap (5.5 eV), high in avalanche breakdown electric field (10 MV/cm), high in saturated carrier mobility (4000 cm²/Vs) and high in the thermal conductivity (20 W/cmK), and is expected as a practically workable element under a high temperature or a radiation exposure environment. So far, in order to develop an electronic element that makes use of these features, a structure and a preparation method of a diamond diode have been proposed.

At the same time, with regard to diamond sensitive to a surface modification, surface inactivation is necessary in order to make use of high breakdown electric field. In other power devices, the surface inactivation technology has been gradually developed (see non-patent literature 1). However, with regard to diamond, an effective measure has not been developed.

In general, in a high-voltage operating diode, in order to inhibit an electric field from concentrating in a margin of an electrode, a guard ring structure using a pn junction, a field plate structure or a combined structure thereof (see non-patent literature 2) has been used. With regard to diamond, p-type and n-type dopings have been realized and a pn junction has been realized as well. However, since the n-type doping is very difficult and a value of leakage current at an interface of a formed pn junction is large (see non-patent literatures 3 and 4), an electric field relaxation technology that realizes a low leakage current under a high voltage in a margin of an electrode has not been obtained yet.

Non-patent literature 1: C. I. Harris et al. “SiC power device passivation using porous SiC” Appl. Phys. Lett. 66 (1995) 1501

Non-patent literature 2: K. Kinoshita et al. “Guard Ring Assisted RESURF”, Proc. 14^{th} ISPSD (2002) p. 253

Non-patent literature 3: S. Koizumi et al. “Formation of diamond p-n junction and its optical emission characteristics”, Diam. Relat. Mater. 11 (2002) p. 307

Non-patent literature 4: T. Makino et al. “Electrical and optical characterization of (001)-oriented homoepitaxial diamond p-n junction”, Diam. Relat. Mater. 15 (2005) p. 513

### SUMMARY OF THE INVENTION

Although diamond has been said to be high in the insulation resistance, the insulation resistance such high as 10 MV/cm has not been utilized effectively. In a Schottky barrier diode, in particular, when a high voltage is applied, it is considered that a leakage current is likely to appear on a surface, whereby the insulation breakdown earlier than a physical property limit is caused.

According to the invention, a surface of diamond is inactivated to provide a high-output diamond semiconductor element that operates up to a high voltage under a low leakage current.

Furthermore, in diamond, the dielectric breakdown of the diamond per se is larger than the dielectric strength of an oxide film. Accordingly, in a conventional voltage resistant structure using SiO₂, the dielectric breakdown of the oxide film precedes thereby being incapable of making use of performance of diamond.

In this connection, according to the invention, a high specific permittivity material is formed on a diamond p⁻ drift layer that is a selected region on p⁻ type diamond to enable to inhibit an electric field from concentrating in a margin of a Schottky electrode, whereby a high-output diamond semiconductor element that operates up to a high voltage at a low leakage current even under a high electric field is provided.

In order to achieve the foregoing objects, the inventors have made intensive studies and found that, when an oxide and a nitride are formed around a Schottky electrode, a diamond surface is inativated and reverse leakage characteristics of diamond are improved, whereby a high-output diamond semiconductor element that may operate under a high voltage at a low leakage current can be obtained.

According to the invention, in a high-output diamond semiconductor element including a Schottky electrode as a cathode, a diamond P⁻ drift layer, a diamond p⁺ ohmic layer, and an ohmic electrode as an anode, an oxygen-terminated diamond surface exposed around the Schottky electrode is inactivated by forming a particular insulating film to shield a surface current path, whereby a high-output diamond semiconductor element that is capable of operating at a low leakage current under a high voltage is realized.

That is, the invention provides, as a first embodiment, the following (1) to (5).

(1) A high-output diamond semiconductor element, comprising:

a Schottky electrode as a cathode,

a diamond P⁻ drift layer,

a diamond p⁺ ohmic layer,

an ohmic electrode as an anode, and

an insulating film layer disposed to surround a circumference of the Schottky electrode.

(2) The high-output diamond semiconductor element according to (1), wherein an insulating material forming the insulating film layer is a nitride or an oxide.

(3) The high-output diamond semiconductor element according to (2), wherein the insulating material is Si₃N₄, SiO₂ or Al₂O₃.

(4) The high-output diamond semiconductor element according to (1), wherein a surface of the diamond joined to the Schottky electrode is oxygen-terminated diamond.

(5) The high-output diamond semiconductor element according to (1), which is a Schottky barrier diode.

Still furthermore, in order to achieve the foregoing objects, the inventors have made intensive studies and found that, when a dielectric layer made of dielectric material is disposed on a part of a junction surface of the Schottky electrode and diamond p⁻ drift layer, and a field plate made of a conductor is disposed on an external surface of the dielectric layer to surround a circumference of the Schottky electrode, a high-output diamond semiconductor element that alleviates an electric field in the proximity of a cathode electrode can be obtained.

According to the invention, in a high-output diamond semiconductor element including a Schottky electrode as a cathode, a diamond P⁻ drift layer, a diamond p⁺ ohmic layer, and an ohmic electrode as an anode, a dielectric layer is disposed on a part of a junction surface of the Schottky electrode and diamond p⁻ drift layer, and furthermore, a field plate made of a conductor is disposed on an external surface of the dielectric layer to surround a circumference of the Schottky electrode, whereby a high-output diamond semiconductor element that alleviates an electric field in the proximity of a cathode electrode is realized.

That is, the invention provides, as a second embodiment, the following (6) to (10).

(6) A high-output diamond semiconductor element, comprising:

a Schottky electrode as a cathode,

a diamond P⁻ drift layer,

a diamond p⁺ ohmic layer,

an ohmic electrode as an anode,

a dielectric layer disposed on a part of a junction surface of the Schottky electrode and the diamond p⁻ drift layer, and

a field plate comprising a conductor, said field plate being disposed on an external surface of the dielectric layer to surround a circumference of the Schottky electrode.

(7) The high-output diamond semiconductor element according to (6), wherein a dielectric material forming the dielectric layer is a dielectric material having a higher dielectric constant than that of the diamond.

(8) The high-output diamond semiconductor element according to (7), wherein the dielectric material is Si₃N₄, Al₂O₃ or SrTiO₃.

(9) The high-output diamond semiconductor element according to (6), wherein a surface of the diamond joined to the Schottky electrode is oxygen-terminated diamond.

(10) The high-output diamond semiconductor element according to (6), which is a Schottky barrier diode.

According to the invention, since the reverse leakage current is reduced, a leakage current at the time of applying a high electric field to a high-output diamond semiconductor element is decreased, an operable voltage is increased, as well as an long-term reliability is improved. Furthermore, since local concentration of an electric field is reduced, a leakage current at the time of applying a high electric field to the high-output diamond semiconductor element is reduced and an operable voltage is increased.

### BRIEF DESCRIPTION OF THE DRAWINGS

FIG. 1 shows a structure where a protective insulating film for inactivation is disposed around a Schottky electrode.

FIG. 2 is a diagram showing difference of a reverse leakage current between example 1 and comparative example 1.

FIG. 3 is a sectional view of a diode that uses a voltage resistance structure utilizing high dielectric constant insulating film.

FIG. 4 is a diagram showing a comparison of reverse breakdown voltages of example 3 and comparative example 2.

FIG. 5 is a diagram showing electric field intensities at A, B, C and D points of examples 3 and 4 and comparative example 2.

### DETAILED DESCRIPTION OF THE INVENTION

The first embodiment of the present invention is explained below.

As an insulating material used in an insulating film that is an inactivating material formed around a Schottky electrode of the invention, a nitride or an oxide may be preferably used, and Si₃N₄, SiO₂ or Al₂O₃ may, for example, be used. An insulating film as an inactivating material is disposed on a surface of a diamond p⁻ drift layer (Schottky electrode side), and the insulating film may be disposed to surround a circumference of the Schottky electrode in accordance with an ion sputtering method, a PLD method, an RF sputtering method or the like. A thickness of the insulating film is not particularly restricted and is, for example, in the range of 1000 Å to 2 μm, and a distance from an adjacent electrode is desirably 10 μm or more.

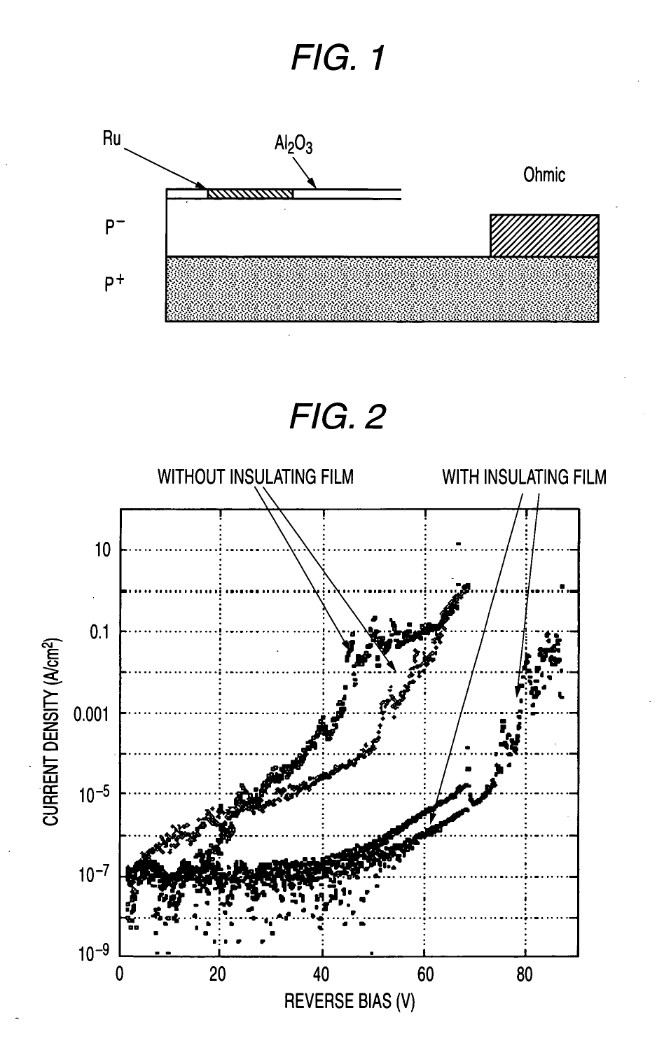

Although the insulating film may have any shape, it usually has an island shape surrounding a circumference of the Schottky electrode (see FIG. 1).

An insulating material used as a surface inactivation material in the invention is preferably a nitride or an oxide, and is for instance, Al₂O₃, Si₃N₄ or SiO₂. It is preferable that at least the material per se has the dielectric strength of 1 MV/cm or more.

The surface inactivation material may be formed in accordance with any conventional method. For example, a wet method using a solvent, a vapor deposition method or a plasma CVD method may be used.

In the invention, the Schottky electrode is a Schottky electrode having a well-known shape for use in power electronics and means a Schottky electrode that executes a well-known operation. A material of the Schottky electrode, so long as it is a metal, is not particularly limited. For instance, Ti, Mo, Ta, Pt, Au and the like may be used.

A Schottky electrode is formed as a pattern electrode constituted of a plurality of electrodes which are formed and scattered to have an island shape on a surface of a 15 diamond semiconductor on a substrate.

The preparation method of a diamond semiconductor used in the invention is not particularly limited. For example, on p- or p⁻-type diamond, a layer of a nitride or an oxide is formed to have a thickness in the range of 0.1 to 10 μm preferably in accordance with an ion beam sputtering method, a PLD method, an RF sputtering method or a CVD method.

In the invention, any types of diamond may be used. Crystal structures such as (001), (111) and (110) may be mentioned. As the diamond surface, carbon-terminated diamond, hydrogen-terminated diamond, oxygen-terminated diamond and the like may be mentioned.

However, regarding at least the diamond joined to the Schottky electrode, a diamond having an oxygen-terminated diamond on the surface thereof is particularly suitable.

In the invention, as to preparation of an ohmic electrode as well, coventional materials and conventional processes may be used in any procedure.

In the next place, the second embodiment of the present invention is explained below.

A material that is used in a field plate of the invention is a conductive material and Pt, a Pt—Ru alloy, a Pt—Ir alloy and the like may be used. A field plate is disposed on an external surface of a dielectric layer and also on a circumferential surface of the Schottky electrode in accordance with an ion sputtering method, a PLD method, an RF method or the like. Namely, the field plate is disposed on an external surface of a dielectric layer to surround a circumference of the Schottky electrode. A thickness of a dielectric layer is substantially ¼ to ¾ a thickness of the Schottky electrode and a sum total of the thickness of the dielectric layer and the thickness of the field plate is desirably substantially same as the thickness of the Schottky electrode.

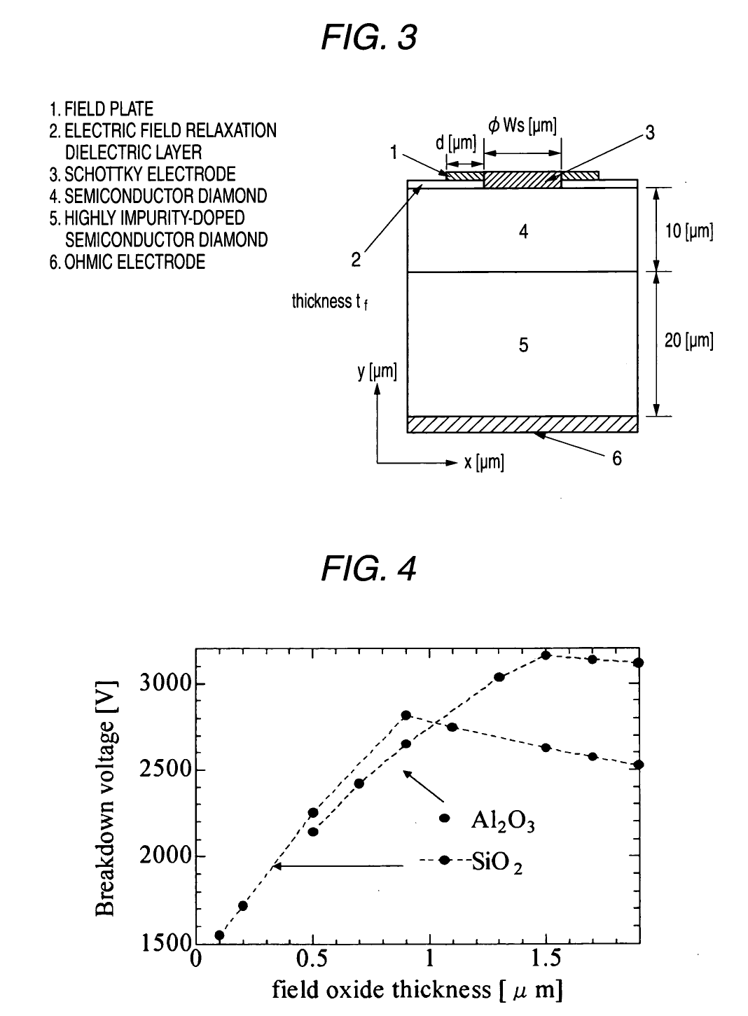

Although the field plate may have any shape, it usually has a circular island shape surrounding a circumference of the Schottky electrode (see FIG. 3).

A dielectric (dielectric material) used in an electric field relaxation dielectric layer according to the invention is, for instance, SiO₂, Si₃N₄, Al₂O₃ or SrTiO₃ and one having a higher specific permittivity than at least that of diamond is selected.

The specific permittivity is 3.9 to 4.1 for SiO₂, 7 to 8 for Si₃N₄, 8.7 to 10 for Al₂O₃, and 200 to 250 for SrTiO₃.

Any conventional method may be used to form a dielectric layer. For example, a method using a solvent, a vapor deposition method and a CVD method may be used.

In the invention, the Schottky electrode is a Schottky electrode having a well-known shape for use in power electronics and means a Schottky electrode that executes a well-known operation. As a Schottky electrode material, a Pt—Ru alloy, a Pt—Ir alloy and the like may be used.

A Schottky electrode is formed as a pattern electrode constituted of a plurality of electrodes which are formed and scattered to have a island shape on a surface of a diamond semiconductor on a substrate.

The preparation method of a diamond semiconductor used in the invention is not particularly limited. Preferably, on p- or p⁻-type diamond, a nitrogen-doped diamond region is formed in accordance with an ion beam sputtering method, a PLD method, a RF sputtering method or a CVD method.

In the invention, any types of diamond may be used. Crystal structures such as (001), (111) and (110) may be mentioned. As the diamond surface, carbon-terminated diamond, hydrogen-terminated diamond, oxygen-terminated diamond and the like may be mentioned.

However, regarding at least the diamond joined to the Schottky electrode, a diamond having an oxygen-terminated diamond on the surface thereof is particularly suitable.

In the invention, as to preparation of an ohmic electrode as well, coventional materials and conventional processes may be used in any procedure.

### EXAMPLES

In the followings, the invention will be more detailed with reference to examples. However, the invention is not limited to these examples.

### Example 1

In the beginning, on oxygen-terminated diamond where a p⁻ film of 1.5 μm was deposited on a p⁺ film, by the use of an electron beam drawing unit, a Schottky electrode pattern having a diameter of 30 μm was prepared, followed by forming a Ru thin film by the use of an RF sputtering unit with a Ru target under conditions of RF output of 200 W and Ar gas flow rate of 10 sccm for 3 min (500 Å). In the next place, similarly, by the use of an electron beam drawing unit, a pattern for protecting a Schottky electrode with a resist was depicted, and, around a Schottky electrode, Al₂O₃ was formed by the use of an RF sputtering unit with a Al₂O₃ target under conditions of RF output of 200 W and Ar gas flow rate of 10 sccm for 70 min (1,000 Å). An ohmic electrode was formed in such a manner that a p⁻ film was partially cut to reach a p⁺ layer by means of the ICP etching, and Ti, Pt and Au were sequentially deposited thereon, followed by annealing at 420° C. for 30 min in an RTA furnace. Consequently, a diamond semiconductor element provided with an insulating film layer around a Schottky electrode was obtained.

### Comparative Example 1

In the beginning, on oxygen-terminated diamond where a p⁻ film of 1.5 μm was deposited on a p⁺ film, by the use of an electron beam drawing unit, a Schottky electrode pattern having a diameter of 30 μm was prepared, followed by forming a Ru thin film by the use of an RF sputtering unit with a Ru target under conditions of RF output of 200 W and Ar gas flow rate of 10 sccm for 3 min (500 Å). An ohmic electrode was formed in such a manner that a p⁻ film was partially cut to reach a p⁺ layer by means of the ICP etching, and Ti, Pt and Au were sequentially deposited thereon, followed by annealing at 420° C. for 30 min in an RTA furnace. Consequently, a diamond semiconductor element provided with an insulating film layer around a Schottky electrode was obtained.

Of a high-output diamond semiconductor element obtained in example 1, voltage-current characteristics were measured. The result is shown in FIG. 2. Furthermore, of a high-output diamond semiconductor element of comparative example 1, that was not covered with an insulating film around a Schottky electrode, voltage-current characteristics were also measured and the result is also shown in FIG. 2. In a device of the invention where a surface inactivation material is formed, it is found that homogenization of performance is achieved and the leakage current caused by a surface is suppressed.

In view of these results, it is found that disposition of an insulating film around a Schottky electrode in order for to inactivation is effective to suppress the leakage current and to homogenize the performance.

### Example 2

As to Si₃N₄ and SiO₂ as well, except that Si₃N₄ and SiO₂ targets were respectively used in place of an Al₂O₃ target, diamond semiconductor elements provided with an insulating film layer around a Schottky electrode were prepared in the same manner as in Example 1.

### Example 3

As a structure of Schottky diode, one obtained in such a manner that, a high concentration ohmic layer where boron had been doped at such a high concentration as 10²⁰ or more was disposed on a Ib (0001) substrate by means of a CVD method, and as a drift layer of 10 μm, a p⁻ low boron concentration layer was disposed thereon at a boron concentration of 5×10¹⁵. Herein, Pt (φ˜2.5 eV) was disposed on a p⁻ drift layer as a Schottky electrode. Further, as an ohmic electrode, a part obtained by cutting a Ib substrate, and laminating Ti of 300 Å, Pt of 300 Å and Au of 1000 Å, respectively on a p⁺ film, followed by annealing at 420° C. for 30 min was used.

A pattern was drawn by the use of a mask using an EB resist or a photoresist, metal for forming a Schottky electrode was deposited, and a lift-off process where the resist is dissolved in a resist peeling liquid to remove an unnecessary portion was executed, to thereby obtain a Schottky electrode having a diameter of 30 μm and a thickness of 5,000 Å. Then, according to the similar patterning, Al₂O₃ was deposited at substantially 1.5 μm by the use of a sputtering device so as to have a diameter twice or more (60 μm or more) the diameter of the Schottky electrode. Thereafter, by the use of a known patterning technique, metal was deposited as a field plate to have a diameter of 45 μm and a thickness of 2,000 Å.

A size of an electrode was set at φ30 μm. An initial breakdown voltage became 880 V, when, with an insulation breakdown due to an avalanche breakdown as a main parameter, a parallel plate model was considered and a simulation was carried out by assuming an electric field of substantially 4.3 MV/cm at the maximum. When an electrode termination is applied on this diamond semiconductor element as shown below, an electric field concentration in diamond is relaxed to thereby largely improve the breakdown voltage.

### Comparative Example 2

In the beginning, a pattern was drawn by the use of a mask using an EB resist or a photoresist and SiO₂ was deposited at 0.75 μm according to a known method. Subsequently, a pattern of a Schottky electrode was drawn by the use of an EB resist so as to overlap with the SiO₂ pattern, and a hole having a diameter of 30 μm was formed for a Schottky electrode by the use of a wet etching method. Similarly, by the use of EB lithography, a pattern (diameter: 60 μm) larger than the hole for the Schottky electrode was drawn, and metal for forming the Schottky electrode was deposited thereto at a thickness of 10,000 Å. A lift-off process where the resist is dissolved in a resist peeling liquid to remove an unnecessary portion was executed, whereby a Schottky electrode having a diameter of contact surface between diamond and a Schottky metal of 30 μm and a diameter including a field plate of 60 μm was obtained.

Of the high-output diamond semiconductor element obtained in example 3, reverse breakdown voltage characteristics in a structure where a low dielectric constant insulating film (SiO₂)-utilizing voltage resistance structure was used in a marginal electric field relaxation layer and a structure where a high dielectric constant insulating film-utilizing voltage resistance structure was used in a marginal electric field relaxation layer were compared (experimental results using Al₂O₃) and the results are shown in FIG. 4.

### Example 4

Except that SrTiO₃ was used in place of Al₂O₃ in a process carried out in example 3, an insulating film was prepared in the same manner as Example 3. Experimental results thereof are shown in FIG. 4.

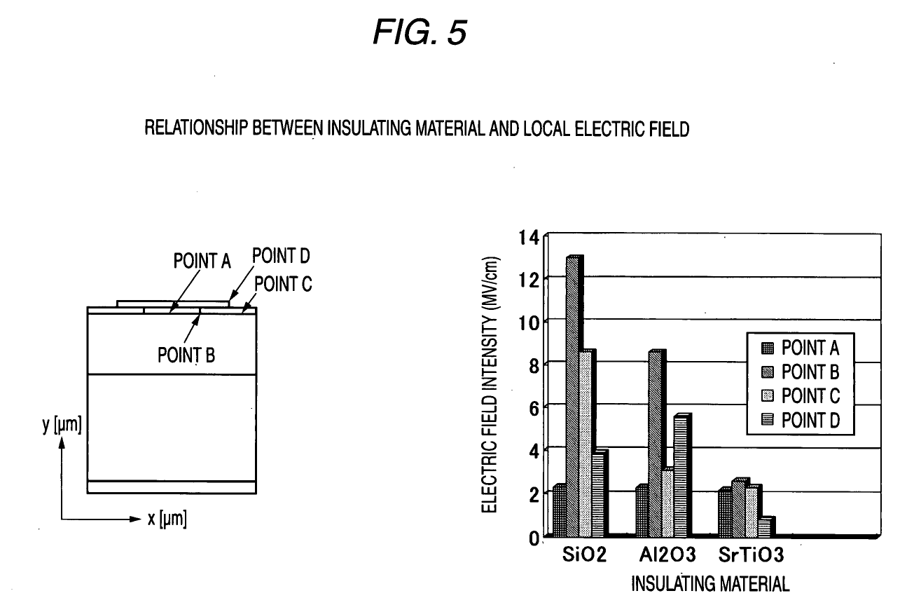

In FIG. 5, a variation of the maximum electric field in diamond when a high dielectric constant material was used is shown.

In this case, 4 points are considered as the places where an electric field concentrates. It is preferable that values of electric field intensities at points A, B, C each are desirably small and close to each other. At a point D, although tolerance ranges differ depending on insulating materials, the value of electric field intensity is desirably as small as possible. In the case of this diode, when a voltage of substantially 1500 V is applied, the minimum value of substantially from 2.2 to 2.3 MV/cm is expected.

As to SiO₂ and Al₂O₃, values in structures optimized in FIG. 4, and, as to SrTiO₃, values substantially same as that of the optimized structure of Al₂O₃ were compared. Accordingly, it was found that, in comparison with SiO₂ (specific permittivity: 3.9) that is smaller in the dielectric constant than diamond (specific permittivity: 5.7), Al₂O₃ (specific permittivity: 8.7) larger in the dielectric constant than diamond reduces the maximum electric field as a whole and makes the difference therebetween smaller. Furthermore, as to SrTiO₃ (specific permittivity: 200) that has very large dielectric constant, electric fields at points A, B and C may be said substantially uniform. The D point as well has a very small value. Accordingly, it is found that a voltage resistance structure that uses an insulating material having high dielectric constant is effective in improving performance of a device.

As described above, it is found that a high-output diamond semiconductor element of the invention may be diverted to a diamond Schottky barrier diode, a diamond pn diode, a diamond thyristor, a diamond transistor and a diamond field effect transistor, and is very high in the industrial applicability.

While the present invention has been described in detail and with reference to specific embodiments thereof, it will be apparent to one skilled in the art that various changes and modifications can be made therein without departing from the scope thereof.

This application is based on Japanese patent application No. 2007-217412 filed Aug. 23, 2007 and Japanese patent application No. 2007-251370 filed Sep. 27, 2007, the entire contents thereof being hereby incorporated by reference.

Further, all references cited herein are incorporated in their entireties.

What is claimed is:

1. A high-output diamond semiconductor element, comprising:
a Schottky electrode as a cathode,
a diamond P⁻ drift layer,
a diamond p⁺ ohmic layer,
an ohmic electrode as an anode, and
an insulating film layer disposed to surround a circumference of the Schottky electrode.

2. The high-output diamond semiconductor element according to claim 1, wherein an insulating material forming the insulating film layer is a nitride or an oxide.

3. The high-output diamond semiconductor element according to claim 2, wherein the insulating material is Si₃N₄, SiO₂ or Al₂O₃.

4. The high-output diamond semiconductor element according to claim 1, wherein a surface of the diamond joined to the Schottky electrode is oxygen-terminated diamond.

5. The high-output diamond semiconductor element according to claim 1, which is a Schottky barrier diode.

6. A high-output diamond semiconductor element, comprising:
a Schottky electrode as a cathode,
a diamond P⁻ drift layer,
a diamond p⁺ ohmic layer,
an ohmic electrode as an anode,
a dielectric layer disposed on a part of a junction surface of the Schottky electrode and the diamond p⁻ drift layer, and
a field plate comprising a conductor, said field plate being disposed on an external surface of the dielectric layer to surround a circumference of the Schottky electrode.

7. The high-output diamond semiconductor element according to claim 6, wherein a dielectric material forming the dielectric layer is a dielectric material having a higher dielectric constant than that of the diamond.

8. The high-output diamond semiconductor element according to claim 7, wherein the dielectric material is Si₃N₄, Al₂O₃ or SrTiO₃.

9. The high-output diamond semiconductor element according to claim 6, wherein a surface of the diamond joined to the Schottky electrode is oxygen-terminated diamond.

10. The high-output diamond semiconductor element according to claim 6, which is a Schottky barrier diode.
